(19) United States
(12) Patent Application Publication
(10) Pub. No.: US 2008/0239688 A1
(43) Pub. Date: Oct. 2, 2008

(54) OPEN RAIL CARD CAGE

(75) Inventors: Jennifer L. Casey, Eagan, MN (US); Michael J. Wayman, Waconia, MN (US)

Correspondence Address: FOGG & POWERS LLC, 10 SOUTH FIFTH STREET, SUITE 1000, MINNEAPOLIS, MN, 55402, US

(73) Assignee: ADC TELECOMMUNICATIONS, INC., Eden Prairie, MN (US)

(21) Appl. No.: 11/691,985

(22) Filed: Mar. 27, 2007

(51) Int. Cl. H05K 7/14; H05K 7/18

(52) U.S. Cl. 361/796

(57) ABSTRACT

An open rail card cage for electronic assemblies is disclosed. The open rail card cage includes a base, an inlet side attached to the base, an outlet side attached to the base, the outlet side offset from the inlet side, a plurality of rail mounts attached to the base and positioned between the inlet side and the outlet side, wherein the plurality of rail mounts further comprise sets of layered guide rails that orient the electronic assemblies parallel to a direction of an airflow between the inlet side and the outlet side, and at least one first set of the layered guide rails spaced apart from at least one second set of the layered guide rails by at least one first air vent.

This application is related to commonly assigned U.S. patent application Ser. No. ______, (Attorney Docket No. 100.853US01), filed on even date herewith and entitled “RECONFIGURABLE MOUNTING BRACKET” (the '853 application). The '853 application is incorporated herein by reference.

### BACKGROUND

In wireless communication networks, such as cellular networks, network operators typically own and operate their own base station equipment. In urban areas, costs for installing new base stations are readily recovered because of increased revenues from additional wireless network subscribers. However, network operators have less economic incentive to invest in the installation (or upgrading) of new base station equipment for similar subscribers in rural or isolated areas since the prospects for growth in the installed subscriber base are significantly more limited. Cost-effective base station equipment is necessary to meet these additional demands.

Additionally, the increased service demands involve operating the networks at optimal speeds to accommodate the additional voice and data traffic on the network. Typically, a host chassis that contains the base station equipment will require additional signal amplification to meet these demands. The additional signal amplification translates into increased thermal energy (heat) within the host chassis. Any excessive heat is transferred either to other areas within the host chassis or from the host chassis to an environment surrounding the host chassis. Losing even a single base station in the network due to inadequate cooling has significant economic and reliability implications.

### SUMMARY

The following specification discusses an open rail card cage. This summary is made by way of example and not by way of limitation. It is merely provided to aid the reader in understanding some aspects of one or more embodiments described in the following specification.

Particularly, in one embodiment, an open rail card cage for electronic assemblies is provided. The open rail card cage includes a base, an inlet side attached to the base, an outlet side attached to the base, the outlet side offset from the inlet side, a plurality of rail mounts attached to the base and positioned between the inlet side and the outlet side, wherein the plurality of rail mounts further comprise sets of layered guide rails that orient the electronic assemblies parallel to a direction of an airflow between the inlet side and the outlet side, and at least one first set of the layered guide rails spaced apart from at least one second set of the layered guide rails by at least one first air vent.

### DRAWINGS

These and other features, aspects, and advantages are better understood with regard to the following description, appended claims, and accompanying drawings where:

FIG. 1 is a block diagram of an electronic device;

FIG. 2 is an elevational view in cross-section illustrating a chassis for the device of FIG. 1 with an open rail card cage;

FIG. 3 is a side elevational view of the chassis of FIG. 2;

FIG. 4 is an alternate side elevational view of the chassis of FIG. 2;

FIG. 5 is an exploded elevational view in cross-section illustrating the chassis of FIG. 2;

FIGS. 6 and 7 are side elevational views of an embodiment of guide rails for the open rail card cage of FIG. 5;

FIGS. 8 and 9 are side elevational views of an alternate embodiment of guide rails for the open rail card cage of FIG. 5; and

FIG. 10 is a flow diagram illustrating an embodiment of a method for manufacturing the open rail card cage.

Reference characters denote similar elements throughout the figures and text of the specification.

### DETAILED DESCRIPTION

The following detailed description describes at least one embodiment for an open rail card cage with layered guide rails. The layered guide rails support a plurality of electronic assemblies coupled to an equipment chassis backplane. Advantageously, the layered guide rails allow for substantially effective forced convection cooling (that is, directed air) of one or more alignments (layers) of the electronic assemblies with suitably large open slots placed between the layered guide rails. In order for the forced convection cooling to reach all components, the suitably large open slots do not restrict airflow within the chassis, decreasing the ambient temperature inside the chassis.

For the plurality of electronic assemblies within the open rail card cage, the electronic assembly alignment closest to the chassis outlet is cooled with substantially the same amount of directed air as the electronic assembly alignment closest to the inlet of the chassis. In at least one implementation, at least one (removable) fan assembly circulates the directed airflow through the chassis. Additionally, the open rail card cage positions the plurality of electronic assemblies such that all assembled electronic components have access to direct airflow in order to operate below prescribed component operating temperature ranges. The open rail card cage and the host chassis enclosure are fabricated with cost-effective material that meets all required telecommunication equipment standards.

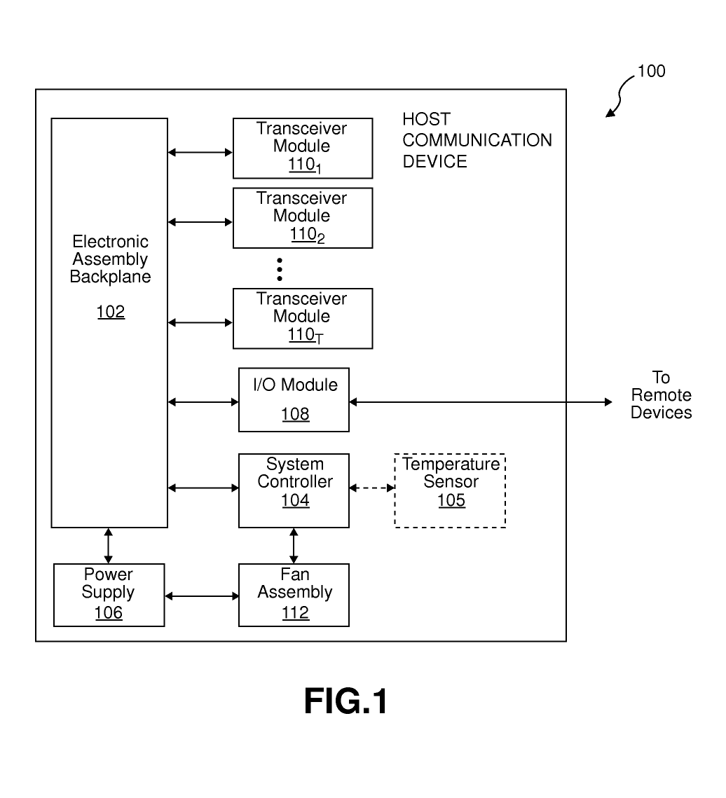

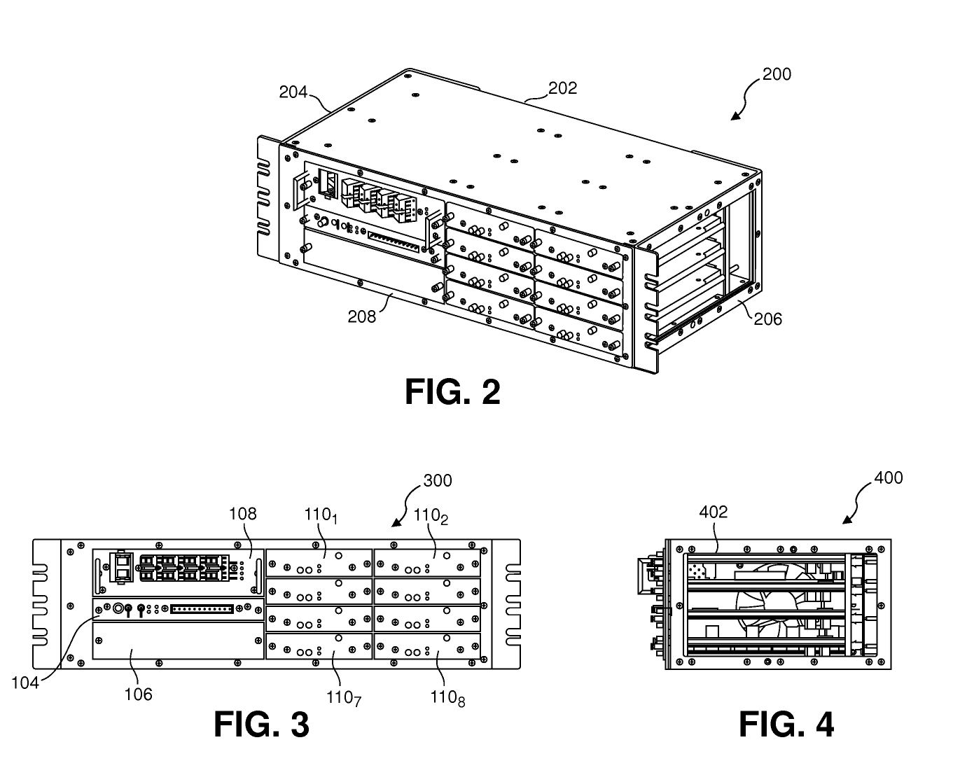

FIG. 1 is a block diagram of an electronic device 100, indicated as a host communication device 100. The device 100 comprises an electronic assembly backplane 102, a system controller 104, a power supply 106, an input/output module 108, and transceiver modules 110₁ to 110_{T}. In the example embodiment of FIG. 1, the system controller 104, the power supply 106, the input/output module 108, and the transceiver modules 110₁ to 110_{T} are communicatively coupled to the electronic assembly backplane 102 and supported by an open rail card cage, as further described below with respect to FIGS. 2 to 5. It is understood that the device 100 is capable of accommodating any appropriate number of the input/output modules 108 and the transceiver modules 110 (for example, at least one input/output module 108, and at least one transceiver module 110) in a single device 100. In the example embodiment of FIG. 1, the power supply 106 supplies electrical power to the device 100 and a fan assembly 112. The fan assembly 112 is controlled by the system controller 104. The input/output module 108 sends and receives communication data between at least one remote (external) communication device (not shown) and the device 110 for further processing by each of the transceiver modules 110₁ to 110_{T}. The device 100 further includes (an optional) temperature sensor 105 responsive to the fan assembly 112 through the system controller 102.

In operation, the plurality of electronic assemblies (for example, the system controller 104, the power supply 106, the input/output module 108, and the transceiver modules 110₁ to 110_{T}) are supported by the open rail card cage between an inlet side and an outlet side of the device 100. The open rail card cage positions one or more sets of the electronic assemblies such that at least one first set and at least one second set of layered guide rails allow the electronic assemblies to be cooled below a prescribed temperature threshold by the fan assembly 112. In at least one example embodiment of FIG. 1, the prescribed temperature threshold is measured by the (optional) temperature sensor 105. Moreover, the fan assembly 112 is a variable-speed removable fan assembly in communication with the temperature sensor 105. The variable-speed removable fan assembly 112 operates at one or more speeds depending on the temperature level that the temperature sensor 105 records. Alternatively, the fan assembly 112 operates continuously. The open rail card cage design as taught in the present application increases airflow within the device 100. The open rail card cage allows the fan assembly 112 to supply substantially the same amount of directed air from the electronic assembly closest to the inlet side of the device 100 to the electronic assembly closest to the outlet side of the device 100.

FIG. 2 is an elevational view in cross-section illustrating an electronics chassis 200 with an open rail card cage. The chassis 200 comprises an enclosure 202 having an inlet side 204 (for example, an air intake), an outlet side 206 (for example, an air exhaust), and an access panel side 208. In at least one embodiment, the enclosure 202 is composed of metal. It is understood that any material that satisfies telecommunication equipment fabrication standards is suitable for the enclosure 202. The enclosure 202 encloses an open rail card cage 402, illustrated from a side view perspective in FIG. 4.

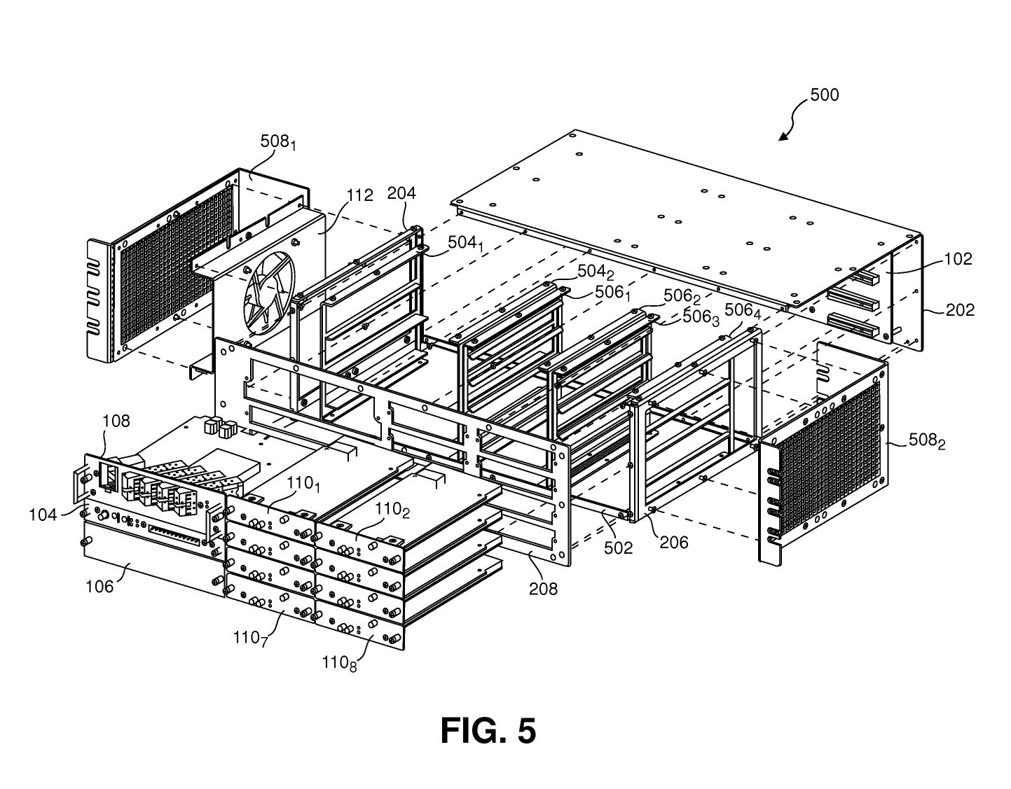

FIG. 3 illustrates the plurality of electronic assemblies accessible from the access panel side 208, including the input/output module 108, the system controller 104, the power supply 106, and the transceiver modules 110₁ to 110_{T} discussed above with respect to FIG. 1. In the example embodiment of FIG. 3, the input/output module 108, the system controller 104, the power supply 106, and the transceiver modules 110₁ to 110₈ are communicatively coupled to the electronic assembly backplane 102 as discussed below with respect to FIG. 5.

FIG. 5 is an exploded view of the chassis 200 and the open rail card cage 402, including mounting brackets 508₁ and 508₂. The open rail card cage 402 comprises a base 502, first rail mounts 504₁ to 504₂, and second rail mounts 506₁ to 506₄. The inlet side 204 of FIG. 2 is attached to the base 502. The outlet side 206 of FIG. 2 (attached to the base 502) is substantially opposed to (offset from) the inlet side 204 as illustrated in FIG. 5. The mounting brackets 508₁ and 508₂ are described in further detail in the '853 application.

In the example embodiment of FIG. 5, the fan assembly 112 is configured to circulate the airflow between the inlet side 204 and the outlet side 206. In at least one implementation, the fan assembly 112 is removable. In alternate implementations, the fan assembly 112 is integrated into the inlet side 204. The fan assembly 112 supplies the directed air at one or more fan speeds depending on an ambient temperature within the open rail card cage 402. The system controller 104, the power supply 106, and the input/output module 108 are inserted in at least one first set of layered guide rails within the first rail mounts 504₁ and 504₂. The at least one first set of layered guide rails allow the system controller 104, the power supply 106 and the input/output module 108 to be cooled below the prescribed temperature threshold discussed above in FIG. 1.

The transceiver modules 110₁ to 110₈ are inserted within the second rail mounts 506₁ to 506₄ such that at least one second set of layered guide rails align the transceiver modules 110₁ to 110₈ in a second rail mount alignment for cooling below the prescribed temperature threshold. The prescribed temperature threshold does not exceed a prescribed electronic component temperature operating range for the plurality of electronic assemblies positioned within the layered guide rails of FIG. 5. As discussed above, each of the layered guide rail sets, the base 502 and the associated rail mounts 504 and 506 form the open rail card cage 402. The open rail card cage 402 supports the plurality of electronic assemblies when the electronic assemblies are operatively coupled to the backplane 102. Each electronic assembly is accessible for servicing from the access panel side 208 of the card cage 402 when the card cage 402 is mounted inside the enclosure 202.

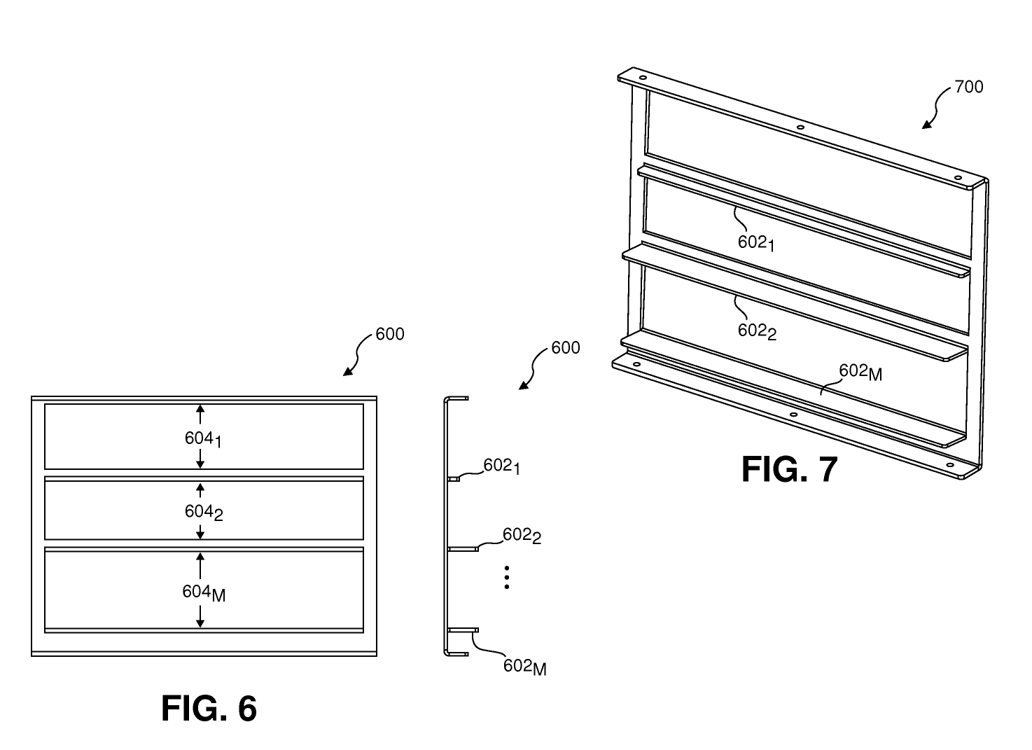

The open rail card cage 402 channels airflow throughout the enclosure 202 to provide uniformity of airflow through enclosure 202 with at least one air vent in the rail mounts 504 and 506 (discussed below) to avoid unnecessary airflow restrictions. The open rail card cage 402 orients the plurality of electronic assemblies (for example, the transceiver modules 110) parallel to the direction of air flow such than when the plurality of electronic assemblies are installed into the rail mounts 504 and 506, the plurality of electronic assemblies further avoid unnecessary airflow restrictions. As a result, a rail mount closest to the outlet side 206 (for example, the at least one first set of layered guide rails within the first set of rail mounts 504₁ and 504₂) is supplied with substantially the same volume of directed air as the rail mount alignment closest to the inlet side 204 (for example, the at least one second set of layered guide rails within the set of rail mounts 506₃ and 506₄). Each of the at least one first and second sets of layered guide rails are further described below with respect to FIGS. 6 to 9.

FIGS. 6 and 7 are side elevational views of an embodiment of rail mounts for the open rail card cage 402, indicated generally at reference numerals 600 and 700, respectively. The rail mounts 600 and 700 comprise guide rails 602₁ to 602_{M}. In one implementation, each of the guide rails 602₁ to 602_{M} support one side of an electronic assembly inserted into the access panel side 208 of the enclosure 202, such as the input/output module 108, the system controller 104, and the power supply 106 discussed above with respect to FIGS. 1 and 5. The second side of the electronic assembly is supported by a corresponding guide rail 602₁ to 602_{M} located on an opposing rail mount. The layered guide rails 602₁ to 602_{M} are separated by air vents 604₁ to 604_{M} that allow air to flow through the rail mounts 600 and 700 and across any electronic assembly supported by the guide rails 602₁ to 602_{M}. Further, the spacing interval of the air vents 604₁ to 604_{M} accommodates the alignment of the electronic assemblies into an orientation that avoid unnecessary airflow restrictions. The spacing intervals provided by the air vents 604₁ to 604_{M} increase the airflow through the enclosure 202 and allow each of the electronic assembly types discussed here to be cooled below the prescribed temperature threshold.

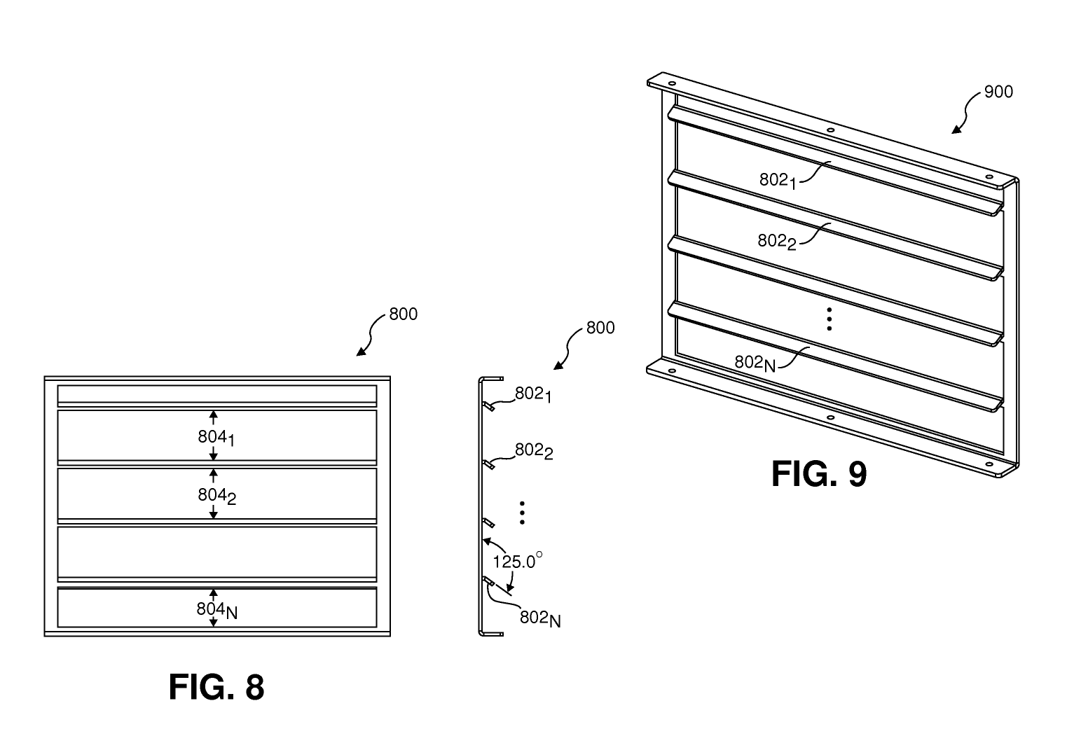

FIGS. 8 and 9 are side elevational views of an alternate embodiment of rail mounts for the open rail card cage 402, indicated generally at reference numerals 800 and 900, respectively. The rail mounts 800 and 900 comprise guide rails 802₁ to 802_{N}. In one implementation, the guide rails 802₁ to 802_{N} are aligned 125° from vertical as illustrated in FIG. 8. Each of the guide rails 802₁ to 802_{N} support one side of an electronic assembly inserted into the access panel side 208 of the enclosure 202, such as the transceiver module 110 discussed above with respect to FIG. 3. The second side of the electronic assembly is supported by a corresponding guide rail 802₁ to 802_{N} located on an opposing rail mount. The layered guide rails 802₁ to 802_{N} are separated by air vents 804₁ to 804_{N} that allow air to flow through the rail mounts 800 and 900 and across any electronic assembly supported by the guide rails 802₁ to 802_{N}. Further, the spacing interval of the air vents 804₁ to 804_{N} accommodates the alignment of the electronic assemblies into an orientation that avoid unnecessary airflow restrictions. The spacing intervals provided by the air vents 804₁ to 804_{N} increase the airflow through the enclosure 202 and maintains the component temperature for each of the electronic assembly types discussed here below the prescribed temperature threshold.

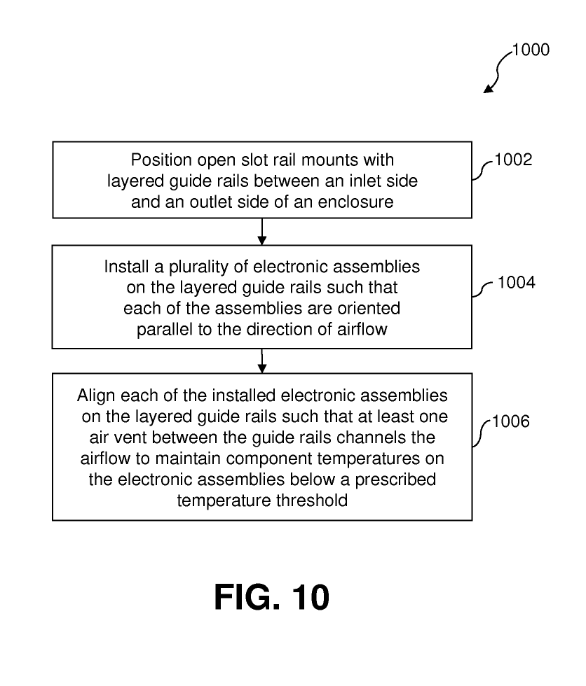

FIG. 10 is a flow diagram illustrating a method 1000 for manufacturing the enclosure 202 for the device 100. The method 1000 addresses maintaining component temperature for the plurality of electronic assemblies coupled to the electronic assembly backplane 102. FIG. 10 begins at block 1002. At block 1002, a plurality of open slot rail mounts 504 and 506 with layered guide rails (the guide rails 602₁ to 602_{M} and 802₁ to 802_{N}, for example) are positioned between the inlet side 204 and the outlet side 206 of the enclosure 202 to form the open rail card cage 402. The open rail card cage 402 accommodates one or more vertical layers of the electronic assemblies, where each vertical layer supports at least one type of electronic assembly as illustrated above with respect to FIGS. 6 to 9.

At block 1004, a plurality of electronic assemblies such as the input/output module 108, the system controller 104, the power supply 106 and the transceiver modules 110 are installed on the layered guide rails 602 and 802 such that each of the electronic assemblies are oriented parallel to the direction of an airflow to avoid unnecessary restrictions when the electronic assemblies are connected to the backplane 102. Each of the electronic assemblies is installed to ensure service access to the plurality of electronic assemblies from a single side of the enclosure 202. The plurality of electronic assemblies are aligned at block 1006 such that at least one air vent (the air vents 604₁ to 604_{M} and 804₁ to 804_{N}, for example) between the guide rail layers 602 and 802 channels the airflow to maintain the component temperatures for the plurality of electronic assemblies below a prescribed temperature threshold. To decrease the ambient temperature within the enclosure 202 (in one implementation), the fan assembly 112 directs the channeled airflow and varies a fan speed based on the current ambient temperature measured by the temperature sensor 105.

This description has been presented for purposes of illustration, and is not intended to be exhaustive or limited to the form (or forms) disclosed. Furthermore, the present application is intended to cover any logical, electrical, or mechanical modifications, adaptations, or variations which fall within the scope of the following claims.

What is claimed is:

1. An open rail card cage for electronic assemblies, comprising:
a base;
an inlet side attached to the base;
an outlet side attached to the base, the outlet side offset from the inlet side;
a plurality of rail mounts attached to the base and positioned between the inlet side and the outlet side, wherein the plurality of rail mounts further comprise sets of layered guide rails that orient the electronic assemblies parallel to a direction of an airflow between the inlet side and the outlet side; and
at least one first set of the layered guide rails spaced apart from at least one second set of the layered guide rails by at least one first air vent.

2. The card cage of claim 1, and further comprising a fan assembly configured to circulate the airflow between the inlet side and the outlet side.

3. The card cage of claim 2, wherein the fan assembly is integrated into the inlet side.

4. The card cage of claim 2, wherein the fan assembly comprises a variable-speed fan that supplies the directed air at one or more fan speeds depending on an ambient temperature within the open rail card cage.

5. The card cage of claim 1, wherein the outlet side opposes the inlet side.

6. The card cage of claim 1, wherein the at least one first air vent channels the airflow to maintain the electronic assemblies below a prescribed temperature threshold.

7. The card cage of claim 6, wherein the prescribed temperature threshold does not exceed a prescribed electronic component temperature operating range.

8. The card cage of claim 1, wherein the plurality of rail mounts accommodate at least one alignment of the electronic assemblies.

9. The card cage of claim 1, wherein each of the sets of guide rails support the electronic assemblies when the electronic assemblies are operatively coupled to a backplane.

10. The card cage of claim 1, wherein the electronic assemblies are accessible for servicing from a single side of the card cage when the card cage is mounted in an enclosure.

11. The card cage of claim 10, wherein the enclosure is composed of metal.

12. A support apparatus in an electronic enclosure, the apparatus comprising:
means for supporting a plurality of electronic assemblies between an inlet side and an outlet side of the enclosure, wherein the means for supporting orients the plurality of electronic assemblies parallel to a direction of an airflow between the inlet side and the outlet side;
means, associated with the means for supporting, for channeling the airflow through the means for supporting; and
means, associated with the means for supporting and the means for channeling, for cooling the plurality of electronic assemblies below a prescribed temperature threshold.

13. The apparatus of claim 12, wherein the means for supporting include at least one set of layered guide rails within an open rail card cage.

14. The apparatus of claim 12, wherein the means for channeling include at least one air vent between sets of the means for supporting.

15. The apparatus of claim 12, wherein the means for cooling include:
a temperature sensor; and
a variable-speed fan assembly in communication with the temperature sensor, the variable-speed fan assembly operates at one or more speeds depending on the temperature level that the temperature sensor records.

16. An electronics chassis, comprising:
an electronic assembly backplane;
a fan assembly positioned at an air intake for the enclosure, the fan assembly in communication with the electronic assembly backplane;
a plurality of electronic assemblies in communication with the electronic assembly backplane;
an open rail card cage having sets of open slot rail mounts configured to orient the plurality of electronic assemblies parallel to a direction of an airflow, the sets of open slot rail mounts having at least one first set of layered guide rails spaced apart from at least one second set of the layered guide rails by at least one first air vent; and
wherein the at least one first air vent channels the airflow to maintain component temperatures on the plurality of electronic assemblies below a prescribed temperature threshold.

17. The chassis of claim 16, wherein the plurality of electronic assemblies comprise at least one of:
a system controller inserted in the at least one first set of the layered guide rails within a first set of the open slot rail mounts;
an input/output module in communication with the system controller and at least one external device, the input/output module operable to send and receive communication data between at least one external device and the system controller; and
a plurality of transceiver modules in communication with the input/output module and the system controller, each of the plurality of transceiver modules inserted within at least one second set of open slot rail mounts.

18. The chassis of claim 17, and further comprising an optional temperature sensor in communication with the system controller.

19. The chassis of claim 18, wherein the optional temperature sensor ensures that the temperature threshold does not exceed a prescribed electronic component temperature operating range.

20. The chassis of claim 17, wherein the input/output module is inserted within the first set of the open slot rail mounts that includes the system controller.

21. The chassis of claim 16, wherein the chassis is a host communications device.

22. The chassis of claim 16, wherein the fan assembly is removable.

23. The chassis of claim 16, wherein the fan assembly comprises a variable-speed fan that operates at one or more fan speeds based on the temperature level measured within the open rail card cage.

24. A method for manufacturing an electronics enclosure, the method comprising:
positioning open slot rail mounts between an inlet side and an outlet side of the enclosure, the open slot rail mounts including sets of layered guide rails;
installing a plurality of electronic assemblies on the layered guide rail sets such that each of the electronic assemblies is oriented parallel to the direction of airflow; and
wherein the installed electronic assemblies are aligned on the layered guide rails such that at least one air vent between the guide rail layers channels the airflow to maintain component temperatures on the plurality of electronic assemblies below a prescribed temperature threshold.

25. The method of claim 24 and further comprising installing at least one removable fan assembly directed at the open slot rail mounts to decrease the ambient temperature within the enclosure.

26. The method of claim 24, wherein positioning the open slot rail mounts comprises:
accommodating one or more vertical sets of layered guide rails, each vertical layer supporting at least one type of the electronic assemblies; and
supporting the electronic assemblies when each of the electronic assemblies is connected to a backplane.

27. The method of claim 24, wherein installing the plurality of electronic assemblies further comprises ensuring service access to each of the electronic assemblies from a single side of the enclosure.
